(19) United States
(12) Patent Application Publication
(10) Pub. No.: US 2011/0000618 A1
(43) Pub. Date: Jan. 6, 2011

(54) APPARATUS AND METHOD FOR PROCESSING SUBSTRATE

(75) Inventor: Il-Kwang Yang, Yongin-si (KR)

Correspondence Address: LRK Patent Law Firm, 1952 Gallows Rd, Suite 200, Vienna, VA, 22182, US

(73) Assignee: EUGENE TECHNOLOGY CO., LTD., Yongin-si (KR)

(21) Appl. No.: 12/867,765

(22) PCT Filed: Feb. 20, 2009
(86) PCT No.: PCT/KR09/00811

§ 371 Date: Aug. 16, 2010

(30) Foreign Application Priority Data
Feb. 22, 2008 (KR) 10-2008-0016142

(51) Int. Cl. H01L 21/306; C23F 1/08

(52) U.S. Cl. 156/345.33; 156/345.1

(57) ABSTRACT

A substrate processing apparatus includes a chamber defining a creation space where radicals are created and a process space where a process is carried out with respect to a substrate, a first supply member configured to supply a first source gas into the creation space, an upper plasma source configured to generate an electric field in the creation space to create the radicals from the first source gas, a second supply member configured to supply a second source gas into the process space, and a lower plasma source configured to generate an electric field in the process space. The upper plasma source includes a first segment and a second segment configured to wrap a side of the chamber. The first and second segments are alternately disposed in the vertical direction of the chamber.

### TECHNICAL FIELD

The present invention relates to an apparatus and method for processing a substrate, and, more particularly, to an apparatus and method for processing a substrate using plasma.

### BACKGROUND ART

A semiconductor device has a plurality of layers on a silicon substrate. The layers are deposited on the substrate through a deposition process. The deposition process has several important issues, which are important in evaluating deposited films and selecting a deposition method.

One of the important issues is quality of the deposited films. The quality includes composition, contamination level, defect density, and mechanical and electrical properties. The composition of films may change depending upon deposition conditions, which is very important in obtaining a specific composition.

Another important issue is uniform thickness over a wafer. In particular, the thickness of a film deposited at the top of a nonplanar pattern having a step is very important. Whether the thickness of the deposited film is uniform or not may be determined by a step coverage defined as a value obtained by dividing the minimum thickness of the film deposited at the step part by the thickness of the film deposited at the top of the pattern.

Another issue related to the deposition is space filling, which includes gap filling to fill gaps defined between metal lines with an insulation film including an oxide film. The gaps are provided to physically and electrically insulate the metal lines.

Among the above-described issues, the uniformity is one of the important issues related to the deposition process. A nonuniform film causes high electrical resistance on the metal lines, which increases a possibility of mechanical breakage.

### DISCLOSURE OF INVENTION

### Technical Problem

It is an object of the present invention to provide an apparatus and method for processing a substrate that is capable of securing process uniformity.

It is another object of the present invention to provide an apparatus and method for processing a substrate that is capable of securing excellent step coverage.

Other objects of the invention will become more apparent from the following detailed description of the present invention and the accompanying drawings.

### Technical Solution

In accordance with one aspect of the present invention, a substrate processing apparatus includes a chamber defining a creation space where radicals are created and a process space where a process is carried out with respect to a substrate, a first supply member configured to supply a first source gas into the creation space, an upper plasma source configured to generate an electric field in the creation space to create the radicals from the first source gas, a second supply member configured to supply a second source gas into the process space, and a lower plasma source configured to generate an electric field in the process space.

The substrate processing apparatus may further include a first power source connected to the upper plasma source for supplying a first electric current to the upper plasma source and a second power source connected to the lower plasma source for supplying a second electric current to the lower plasma source.

The upper plasma source may include a first segment and a second segment configured to wrap a side of the chamber, and the first and second segments may be alternately disposed in the vertical direction of the chamber.

The substrate processing apparatus may further include a support member installed in the chamber. The second supply member may include a spray plate disposed generally in parallel to the substrate placed on the support plate such that an inner space of the chamber is partitioned into the creation space and the process space by the spray plate.

The substrate processing apparatus may further include a second supply line connected to the spray plate for supplying the second source gas to the spray plate. The spray plate may have first spray holes communicatively connected between the creation space and the process space for spraying the first source gas, supplied to the creation space, into the process space, and second spray holes connected to the second supply line for spraying the second source gas into the process space.

The substrate processing apparatus may further include a support member installed in the chamber. The first supply member may include a diffusion plate installed at a ceiling of the chamber opposite to the creation space such that the diffusion plate is disposed generally in parallel to the substrate placed on the support member. A buffer space may be defined between the diffusion plate and the ceiling of the chamber for allowing the first source gas to be supplied thereinto.

The substrate processing apparatus may further include a support member installed in the chamber. The second supply member may include a first spray plate disposed generally in parallel to the substrate placed on the support member, a second spray plate disposed below the first spray plate such that the second spray plate is spaced apart from the first spray plate, and a connection line configured to interconnect a space above the first spray plate and a space below the second spray plate. The creation space may be defined above the first spray plate, and the process space is defined below the second spray plate.

The second supply member may have a supply nozzle disposed between the first and second spray plates, such that a lower end of the supply nozzle corresponds to a center of the substrate placed on the support member, for supplying the second source gas downward.

In accordance with another aspect of the present invention, a substrate processing method includes supplying a first source gas toward a creation space defined in a chamber, generating an electric field in the creation space to create radicals from the first source gas and supplying the created radicals into a process space defined in the chamber, supplying a second source gas into the process space, and generating an electric field in the process space.

The electric fields generated in the creation space and the process space may be different from each other.

### Advantageous Effects

According to the present invention, it is possible to secure excellent step coverage.

### BRIEF DESCRIPTION OF DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a view schematically illustrating a substrate processing apparatus according to an embodiment of the present invention;

FIG. 2 is a view illustrating the bottom of a spray plate of FIG. 1;

FIG. 3 is a view illustrating a diffusion plate of FIG. 1;

FIG. 4 is a view schematically illustrating a substrate processing apparatus according to another embodiment of the present invention;

FIG. 5 is a view illustrating a spray plate of FIG. 4;

FIG. 6 is a view schematically illustrating a substrate processing apparatus according to another embodiment of the present invention; and

FIG. 7 is a view schematically illustrating a substrate processing apparatus according to a further embodiment of the present invention.

FIG. 8 is a view illustrating a lower spray plate of FIG. 7.

### BEST MODE FOR CARRYING OUT THE INVENTION

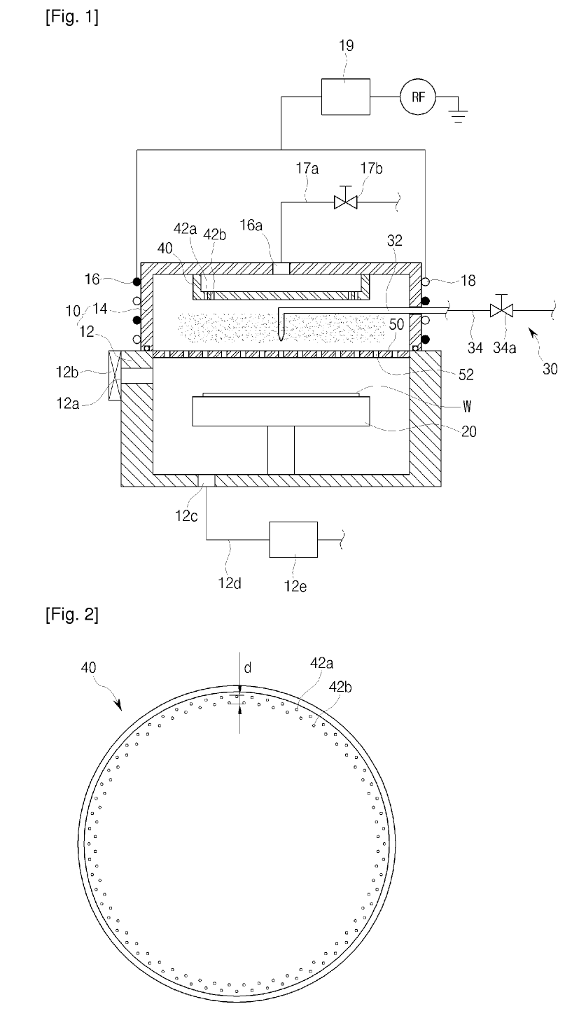

Hereinafter, exemplary embodiments of the present invention will be described in more detail with reference to the accompanying drawings, i.e., FIGS. 1 to 8. Embodiments of the present invention may be modified in various forms, and therefore, the scope of the present invention should not be interpreted to be limited by embodiments which will be described in the following. The embodiments are provided to more clearly describe the present invention to a person having ordinary skill in the art to which the present invention pertains. Consequently, the shape of constituent elements illustrated in the drawings may be exaggerated for a more clear description.

Meanwhile, an inductively coupled plasma (ICP) type plasma process will be described hereinafter as an example, although the present invention is applicable to various plasma processes. Also, a substrate will be described hereinafter as an example, although the present invention is applicable to various objects to be processed.

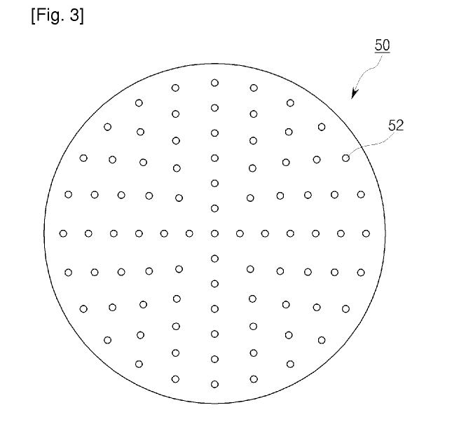

FIG. 1 is a view schematically illustrating a substrate processing apparatus according to an embodiment of the present invention. FIG. 2 is a view illustrating the bottom of a spray plate of FIG. 1, and FIG. 3 is a view illustrating a diffusion plate of FIG. 1.

The substrate processing apparatus includes a chamber 10 defining a process space where a process is carried out with respect to a substrate W. The chamber 10 includes a lower chamber 12 open at the top thereof and an upper chamber 14 configured to close the open top of the lower chamber 12. In the lower chamber 12, a process is carried out with respect to the substrate W. In the upper chamber 14, radicals are generated from a first source gas, which will be described hereinafter.

In the lower chamber 12 is installed a support plate 20. The substrate W is placed on the support plate 20. The substrate W is introduced into the lower chamber 12 through an inlet port 12a formed at one side of the lower chamber 12. The introduced substrate W is placed on the support plate 20. The support plate 20 may be an electrostatic chuck (E-chuck). Also, helium (He) of a predetermined pressure may be sprayed to the rear of the substrate W to accurately control the temperature of the substrate W placed on the support plate 20. The helium exhibits very high thermal conductivity.

At the bottom of the lower chamber 12 is formed an exhaust port 12c. A process gas and reaction by-product are discharged to the outside through an exhaust line 12d connected to the exhaust port 12c. On the exhaust line 12d is installed a pump 12e to forcibly discharge the reaction by-product. Meanwhile, it is possible to reduce the internal pressure of the chamber 10 to a predetermined degree of vacuum through the exhaust port 12c. At the sidewall of the lower chamber 12 is installed a gate valve 12b to open and close the inlet port 12a through which the substrate W is introduced into or removed from the lower chamber 12.

As shown in FIGS. 1 and 2, a spray plate 40 is installed at the ceiling of the upper chamber 14 opposite to the process space. The spray plate 40 is disposed generally in parallel to the substrate W placed on the support plate 20. The spray plate 40 is spaced a predetermined distance from the ceiling of the upper chamber 14 such that a buffer space is defined between the spray plate 40 and the ceiling of the upper chamber 14. At the ceiling of the upper chamber 14 is formed a supply hole 16a. The supply hole 16a is connected to a first supply line 17a. The first supply line 17a supplies a first source gas. The first source gas is supplied into the buffer space through the supply hole 16a. The first source gas supplied into the buffer space is sprayed into the process space through spray holes 42a and 42b formed at the spray plate 40. The first supply line 17a is opened and closed by a valve 17b.

Plasma sources 16 and 18 are installed at the outer circumference of the upper chamber 14. The plasma sources 16 and 18 are disposed in such a manner that the plasma sources 16 and 18 wrap the side of the upper chamber 14. The plasma sources 16 and 18 include a first segment 16 and a second segment 18. The first and second segments 16 and 18 are connected to a radio frequency (RF) generator. Between the first and second segments 16 and 18 and the RF generator is connected a matching unit 19 for impedance matching. The first and second segments 16 and 18 are alternately disposed from the upper end of the upper chamber 14 to the lower end of the upper chamber 14 such that a more uniform electric field is generated in the upper chamber 14.

Radio-frequency current generated from the RF generator is supplied to the first and second segments 16 and 18. The first and second segments 16 and 18 convert the radio-frequency current into a magnetic field, and create radicals from the first source gas supplied into the chamber 10. The first source gas includes nitrous oxide (N₂O) or ammonia (NH₃).

The substrate processing apparatus further includes a supply unit 30. The supply unit 30 includes a supply nozzle 32 installed below the spray plate 40, a second supply line 34 connected to the supply nozzle 32, and a valve 34a configured to open and close the second supply line 34. As shown in FIG. 1, the supply nozzle 32 is installed below the spray plate 40, such that the lower end of the supply nozzle 32 faces the center of the substrate W placed on the support plate 20, for supplying a second source gas toward the center of the substrate W. The second supply line 34 is connected to the supply nozzle 32 for supplying the second source gas to the supply nozzle 32. The second source gas includes a silicon-containing gas, such as silane (SiH₄).

As shown in FIGS. 1 and 3, the substrate processing apparatus further includes a diffusion plate 50 installed at the upper end of the lower chamber 12. The diffusion plate 50 is disposed generally in parallel to the substrate W placed on the support plate 20, and is located below the supply nozzle 32. Above the diffusion plate 50, radicals are created from a first source gas. The created radicals are diffused below the diffusion plate 50 through diffusion holes 52 formed at the diffusion plate 50. Also, the supply nozzle 32 sprays a second source gas above the diffusion plate 50. The sprayed second source gas reacts with the radicals, and, at the same time, is diffused below the diffusion plate 50 through the diffusion holes 52 formed at the diffusion plate 50.

Hereinafter, a substrate processing method according to an embodiment of the present invention will be described in detail with reference to FIGS. 1 to 3. A first source gas, supplied through the first supply line 17a, is supplied into the buffer space defined between the ceiling of the upper chamber 14 and the spray plate 40, and is then supplied into the process space through the spray holes 42a and 42b. The first and second segments 16 and 18, installed at the side of the upper chamber 14, convert radio-frequency current, supplied from the outside, into a magnetic field, and create radicals from the first source gas supplied into the process space. On the other hand, the supply nozzle 32 supplies a second source gas above the diffusion plate 50. The sprayed second source gas reacts with the radicals, and, at the same time, is diffused below the diffusion plate 50 through the diffusion holes 52, formed at the diffusion plate 50, to deposit a film on the substrate W.

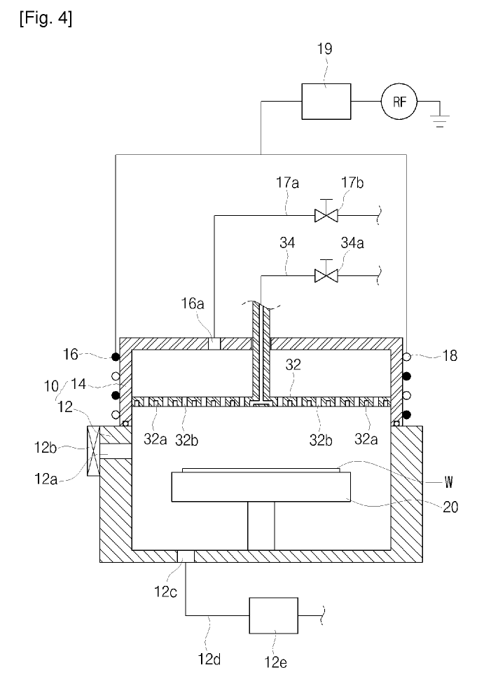

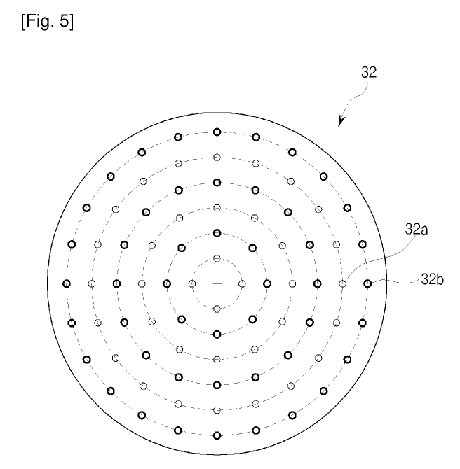

FIG. 4 is a view schematically illustrating a substrate processing apparatus according to another embodiment of the present invention, and FIG. 5 is a view illustrating a spray plate of FIG. 4. Hereinafter, only components of this embodiment distinguished from the previous embodiment shown in FIG. 1 will be described, and the description of omitted components will be understood from the description previously made with reference to FIG. 1.

The supply unit 30 further includes a spray plate 32 disposed above the support plate 20. The spray plate 32 is disposed generally in parallel to the substrate W placed on the support plate 20. The spray plate 32 partitions the process space into a first process space defined above the spray plate 32 and a second process space defined below the spray plate 32. As shown in FIGS. 4 and 5, the spray plate 32 includes first spray holes 32a and second spray holes 32b. The first and second spray holes 32a and 32b are arranged concentrically about the center of the spray plate 32. Also, the first and second spray holes 32a and 32b are alternately disposed from the center of the spray plate 32 to the edge of the spray plate 32.

The first spray holes 32a are communicatively connected to a second supply line 34. The second supply line 34 supplies a second source gas to the first spray holes 32a. The second source gas is supplied into the second process space through the first spray holes 32a. The second spray holes 32b are formed through the spray plate 32 such that the first and second process spaces communicate with each other through the second spray holes 32b.

Hereinafter, a substrate processing method according to an embodiment of the present invention will be described in detail with reference to FIGS. 4 and 5. A first source gas, supplied through the first supply line 17a, is supplied into the first process space defined above the spray plate 32. The first and second segments 16 and 18, installed at the side of the upper chamber 14, convert radio-frequency current, supplied from the outside, into a magnetic field, and create radicals from the first source gas supplied into the process space. The created radicals are supplied into the second process space through the second spray holes 32b of the spray plate 32. On the other hand, the second supply line 34 supplies a second source gas to the first spray holes 32a. The second source gas is supplied into the second process space (defined above the substrate W) through the first spray holes 32a. In the second process space, the second source gas reacts with the radicals to deposit a film on the substrate W.

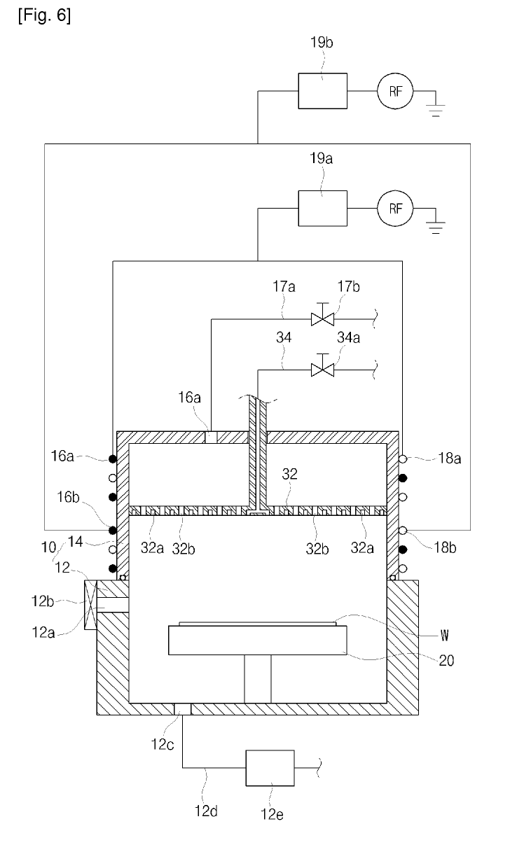

FIG. 6 is a view schematically illustrating a substrate processing apparatus according to another embodiment of the present invention. Hereinafter, only components of this embodiment distinguished from the previous embodiment shown in FIGS. 4 and 5 will be described, and the description of omitted components will be understood from the description previously made with reference to FIGS. 4 and 5.

The plasma sources include upper plasma sources 16a and 18a configured to surround the first process space and lower plasma sources 16b and 18b configured to surround the second process space. The upper plasma sources 16a and 18a and the lower plasma sources 16b and 18b are connected to different radio frequency (RF) generators, respectively. Between the upper plasma sources 16a and 18a and the corresponding RF generator and between the lower plasma sources 16b and 18b and the corresponding RF generator are connected matching units 19a and 19b for impedance matching, respectively.

Also, the upper plasma sources 16a and 18a include a first upper segment 16a and a second upper segment 18a. The lower plasma sources 16b and 18b include a first lower segment 16b and a second lower segment 18b. The first upper segment 16a and the second upper segment 18a are alternately disposed from the upper end of the upper chamber 14 to the height corresponding to the top of the spray plate 32. The first lower segment 16b and the second lower segment 18b are alternately disposed from the height corresponding to the bottom of the spray plate 32 to the lower end of the upper chamber 14. Consequently, it is possible to generate different electric fields or the same electric field above and below the spray plate 32 (for example, intensity or density of the electric field) and thus to control a process rate (for example, uniformity).

Radio-frequency current supplied to the upper plasma sources 16a and 18a from the corresponding RF generator is supplied to the first upper segment 16a and the second upper segment 18a. The first upper segment 16a and the second upper segment 18a convert the radio-frequency current into a magnetic field, and create radicals from the first source gas supplied into the first process space. The created radicals are supplied into the second process space through the second spray holes 23b of the spray plate 32.

Radio-frequency current supplied to the lower plasma sources 16b and 18b from the corresponding RF generator is supplied to the first lower segment 16b and the second lower segment 18b. The first lower segment 16b and the second lower segment 18b convert the radio-frequency current into a magnetic field. Consequently, the radicals, supplied into the second process space, and a second source gas react with each other to deposit a film on the substrate W.

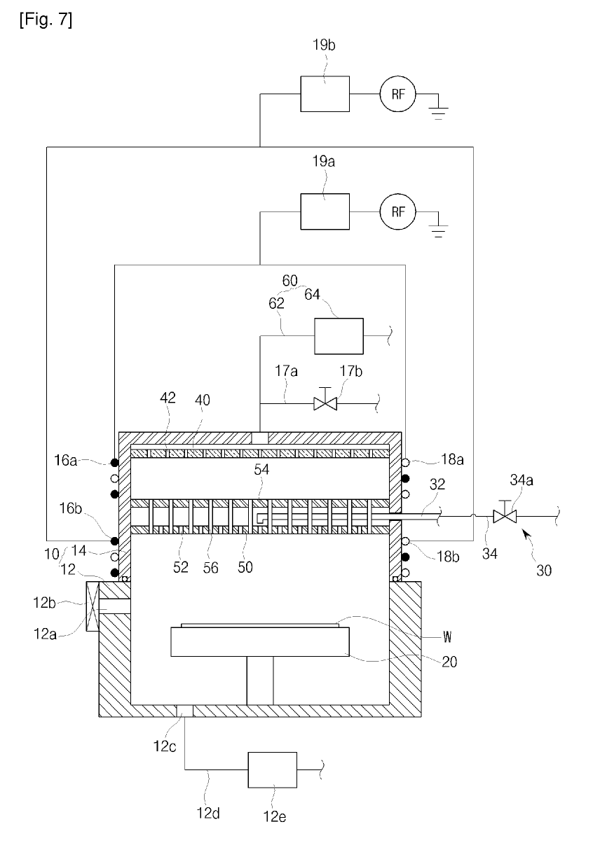

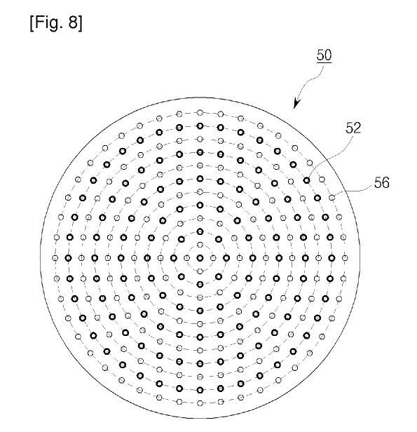

FIG. 7 is a view schematically illustrating a substrate processing apparatus according to a further embodiment of the present invention, and FIG. 8 is a view illustrating a lower spray plate of FIG. 7. Hereinafter, only components of this embodiment distinguished from the previous embodiment shown in FIG. 1 will be described, and the description of omitted components will be understood from the description previously made with reference to FIG. 1.

As shown in FIG. 7, a diffusion plate 40 is installed at the ceiling of the upper chamber 14 opposite to the process space. The diffusion plate 40 is disposed generally in parallel to the substrate W placed on the support plate 20. The diffusion plate 40 is spaced a predetermined distance from the ceiling of the upper chamber 14 such that a buffer space is defined between the diffusion plate 40 and the ceiling of the upper chamber 14. A first source gas, supplied into the buffer space, is diffused into the process space through diffusion holes 42 formed at the diffusion plate 40.

The supply unit 30 further includes first and second spray plates 54 and 50. The first spray plate 54 is disposed generally in parallel to the substrate W placed on the support plate 20. The second spray plate 50 is disposed below the first spray plate 54 such that the second spray plate 50 is spaced apart from the first spray plate 54. The process space is partitioned into a first process space defined above the first spray plate 54 and a second process space defined below the second spray plate 50.

As shown in FIGS. 7 and 8, the supply unit 30 further includes connection lines 56 configured to communicatively interconnect the first and second process spaces. The upper end of each connection line 56 is connected to the first spray plate 54, and the lower end of each connection line 56 is connected to the second spray plate 50. Also, a plurality of spray holes 52 are formed at the second spray plate 50. The spray holes 52 communicate with a space defined between the first spray plate 54 and the second spray plate 50.

Also, as shown in FIG. 7, the supply nozzle 32 is disposed in the space defined between the first spray plate 54 and the second spray plate 50. The lower end of the supply nozzle 32 is disposed, such that the lower end of the supply nozzle 32 faces the center of the substrate W placed on the support plate 20, and therefore, the lower end of the supply nozzle 32 is directed to the center of the substrate W, for supplying a second source gas to the top of the second spray plate 50. Consequently, the second source gas is supplied into the second process space through the spray holes 52.

The plasma sources include upper plasma sources 16a and 18a configured to surround the first process space and lower plasma sources 16b and 18b configured to surround the second process space. The upper plasma sources 16a and 18a and the lower plasma sources 16b and 18b are connected to different radio frequency (RF) generators, respectively. Between the upper plasma sources 16a and 18a and the corresponding RF generator and between the lower plasma sources 16b and 18b and the corresponding RF generator are connected matching units 19a and 19b for impedance matching, respectively.

Also, the upper plasma sources 16a and 18a include a first upper segment 16a and a second upper segment 18a. The lower plasma sources 16b and 18b include a first lower segment 16b and a second lower segment 18b. The first upper segment 16a and the second upper segment 18a are alternately disposed from the upper end of the upper chamber 14 to the height corresponding to the top of the first spray plate 54. The first lower segment 16b and the second lower segment 18b are alternately disposed from the height corresponding to the bottom of the second spray plate 50 to the lower end of the upper chamber 14. Consequently, it is possible to generate different electric fields or the same electric field above the first spray plate 54 and below the second spray plate 50 (for example, intensity or density of the electric field) and thus to control a process rate (for example, uniformity).

Radio-frequency current supplied to the upper plasma sources 16a and 18a from the corresponding RF generator is supplied to the first upper segment 16a and the second upper segment 18a. The first upper segment 16a and the second upper segment 18a convert the radio-frequency current into a magnetic field, and create radicals from the first source gas supplied into the first process space. The created radicals are supplied into the second process space through the spray holes 52 of the second spray plate 50.

Radio-frequency current supplied to the lower plasma sources 16b and 18b from the corresponding RF generator is supplied to the first lower segment 16b and the second lower segment 18b. The first lower segment 16b and the second lower segment 18b convert the radio-frequency current into a magnetic field. Consequently, the radicals, supplied into the second process space, and a second source gas react with each other to deposit a film on the substrate W.

Meanwhile, the substrate processing apparatus further includes a cleaning unit 60 to clean the interior of the chamber 10. The cleaning unit 60 includes a third supply line 62 connected to the first supply line 17a and a generation chamber 64 configured to generate cleaning plasma from a cleaning gas supplied from the outside. The cleaning plasma generated in the generation chamber 64 is supplied into the chamber 10 via the third supply line 62 and the first supply line 17a to clean the interior of the chamber 10. The cleaning gas includes nitrogen trifluoride (NF₃) or argon (Ar).

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

### INDUSTRIAL APPLICABILITY

Apparent from the above description, it is possible to secure excellent step coverage. Consequently, the present invention has industrial applicability.

1. A substrate processing apparatus comprising:
a chamber defining, a creation space where radicals are created and a process space where a process is carried out with respect to a substrate;
a first supply member configured to supply a first source gas into the creation space;
an upper plasma source configured to generate an electric field in the creation space to create the radicals from the first source gas; a second supply member configured to supply a second source gas into the process space; and
a lower plasma source configured to generate an electric field in the process space.

2. The substrate processing apparatus according to claim 1, further comprising:
a first power source connected to the upper plasma source for supplying a first electric current to the upper plasma source; and
a second power source connected to the lower plasma source for supplying a second electric current to the lower plasma source.

3. The substrate processing apparatus according to claim 1, wherein
the upper plasma source comprises a first segment and a second segment configured to wrap a side of the chamber, and
the first and second segments are alternately disposed in a vertical direction of the chamber.

4. The substrate processing apparatus according to claim 1, further comprising:
a support member installed in the chamber, wherein
the second supply member comprises a spray plate disposed generally in parallel to the substrate placed on the support plate such that an inner space of the chamber is partitioned into the creation space and the process space by the spray plate.

5. The substrate processing apparatus according to claim 4, further comprising:
a second supply line connected to the spray plate for supplying the second source gas to the spray plate, wherein
the spray plate has
first spray holes communicatively connected between the creation space and the process space for spraying the first source gas, supplied to the creation space, into the process space, and
second spray holes connected to the second supply line for spraying the second source gas into the process space.

6. The substrate processing apparatus according to claim 1, further comprising:
a support member installed in the chamber, wherein
the first supply member comprises a diffusion plate installed at a ceiling of the chamber opposite to the creation space such that the diffusion plate is disposed generally in parallel to the substrate placed on the support member, and
a buffer space is defined between the diffusion plate and the ceiling of the chamber for allowing the first source gas to be supplied thereinto.

7. The substrate processing apparatus according to claim 1, further comprising:
a support member installed in the chamber, wherein
the second supply member comprises:
a first spray plate disposed generally in parallel to the substrate placed on the support member;
a second spray plate disposed below the first spray plate such that the second spray plate is spaced apart from the first spray plate; and
a connection line configured to interconnect a space above the first spray plate and a space below the second spray plate, and
the creation space is defined above the first spray plate, and the process space is defined below the second spray plate.

8. The substrate processing apparatus according to claim 7, wherein the second supply member has a supply nozzle disposed between the first and second spray plates, such that a lower end of the supply nozzle corresponds to a center of the substrate placed on the support member, for supplying the second source gas downward.

9. A substrate processing method comprising:
supplying a first source gas toward a creation space defined in a chamber;
generating an electric field in the creation space to create radicals from the first source gas and supplying the created radicals into a process space defined in the chamber;
supplying a second source gas into the process space; and
generating an electric field in the process space.

10. The substrate processing method according to claim 9, wherein the electric fields generated in the creation space and the process space are different from each other.

11. The substrate processing apparatus according to claim 2, wherein
the upper plasma source comprises a first segment and a second segment configured to wrap a side of the chamber, and
the first and second segments are alternately disposed in a vertical direction of the chamber.

12. The substrate processing apparatus according to claim 2, further comprising:
a support member installed in the chamber, wherein
the second supply member comprises a spray plate disposed generally in parallel to the substrate placed on the support plate such that yin inner space of the chamber is partitioned into the creation space and the process space by the spray plate.

13. The substrate processing apparatus according to claim 12, further comprising:
a second supply line connected to the spray plate For supplying the second source gas to the spray plate, wherein
the spray plate has
first spray holes communicatively connected between the creation space and the process space for spraying the first source gas, supplied to the creation space, into the process space, and
second spray holes connected to the second supply line for spraying the second source gas into the process space.

14. The substrate processing apparatus according to claim 2, further comprising:
a support member installed in the chamber, wherein
the first supply member comprises a diffusion plate installed at a ceiling of the chamber opposite to the creation space such that the diffusion plate is disposed generally in parallel to the substrate placed on the support member, and
a buffer space is defined between the diffusion plate and the ceiling of the chamber for allowing the first source gas to he supplied thereinto.

15. The substrate processing, apparatus according to claim 2, further comprising:
a support member installed in the chamber, wherein
the second supply member comprises:
a first spray plate disposed generally in parallel to the substrate placed on the support member;
a second spray plate disposed below the first spray plate such that the second spray plate is spaced apart from the first spray plate; and
a connection line configured to interconnect a space above the first spray plate and a space below the second spray plate, and
the creation space is defined above the first spray plate, and the process space is defined below the second spray plate.

16. The substrate processing apparatus according to claim 15, wherein the second supply member has a supply nozzle disposed between the first and second spray plates, such that a lower end of the supply nozzle corresponds to a center of the substrate placed on the support member, for supplying the second source gas downward.
